(19) United States
(12) Patent Application Publication
(10) Pub. No.: US 2009/0272433 A1
(43) Pub. Date: Nov. 5, 2009

(54) Functional Device and Method for Making the Same

(75) Inventors: Masahiro Morooka, Kanagawa (JP); Yusuke Susuki, Kanagawa (JP); Reiko Yoneya, Kanagawa (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 12/226,097

(22) PCT Filed: Mar. 27, 2007
(86) PCT No.: PCT/JP2007/056361

§ 371 Date: Mar. 3, 2009

(30) Foreign Application Priority Data
Apr. 12, 2006 (JP) 2006-109454

(51) Int. Cl. H01L 31/00; H01L 31/18

(52) U.S. Cl. 136/256; 438/64; 257/E21.499

(57) ABSTRACT

To provide a functional device suitable for dye-sensitized solar cells and the like and having a structure suited for thickness reduction, and a method for making the same with good productivity. A dye-sensitized photovoltaic device 10 is constituted by a transparent substrate 1 formed of glass or the like, a transparent conductive layer 2 formed of FTO or the like, semiconductor electrode layers (negative electrodes) 3 supporting a photosensitizing dye, an electrolyte layer 4, a film-shaped counter electrode (positive electrode) 5, a film-shaped packaging member 6 replacing a counter substrate of the related art, a sealing member 7, power-collecting wiring 8, a wiring protecting layer 9, and the like. As the material of the film-shaped packaging member 6, a material that has high barrier property of suppressing passage of solvents, gasses, water, and the like and excellent resistance to organic solvents and heat is preferred. The device 10 is sealed by joining the transparent substrate 1 to the film-shaped packaging member 6 but a part 11b of a joint 11 is left unjoined before introduction of an electrolytic solution so as to function as an introduction port and joined after the introduction of the electrolytic solution, thereby requiring no end seal.

### TECHNICAL FIELD

The present invention relates to functional devices suitable for dye-sensitized solar cells or the like and methods for making such functional devices, and, in particular, to a functional device having a structure suitable for thickness reduction and a method for making such a functional device with high productivity.

### BACKGROUND ART

As an energy source alternative to fossil fuels, solar cells that utilize solar light have drawn attention and various studies are conducted therefor. Solar cells are a type of photovoltaic devices that convert optical energy to electrical energy and are expected to gain further popularity since they use solar light as the energy source and thus have a very little impact on the global environment.

As the principle and materials of the solar cells, various types are investigated. Among these, solar cells that utilize pn junctions of semiconductors are currently most popular, and many solar cells that use silicon as a semiconductor material are commercially available. However, this type of solar cells requires a step of making a highly pure semiconductor material and a step of forming a pn junctions; thus, there are problems such as an increase in the number of production steps and high equipment cost and energy cost due to the necessity of production steps under vacuum.

In this respect, Japanese Patent No. 2664194 (pp. 2 and 3, FIG. 1) proposes a dye-sensitized photochemical cell (photovoltaic device) in which photoinduced electron transfer sensitized by a dye is applied. This type of photovoltaic devices has high photoelectric conversion efficiency, does not require a large-scale manufacturing apparatus such as a vacuum apparatus, and can be manufactured easily and with high productivity by using inexpensive semiconductor materials such as titanium oxide. Thus they are expected to be solar cells of the oncoming generation. In the case of application to solar cells, a substance that can effectively absorb light having a wavelength of 300 to 900 nm near visible light, e.g., a ruthenium complex, is used as a photosensitizing dye.

FIG. 6 is a cross-sectional view showing the structure of a typical dye-sensitized photovoltaic device 100 known in the art. The dye-sensitized photovoltaic device 100 is mainly constituted by a transparent substrate 101 formed of glass or the like, a transparent conductive layer 102 formed of FTO (fluorine-doped tin(IV) oxide, SnO₂) or the like, a semiconductor electrode layer 103 (negative electrode) supporting a photosensitizing dye, an electrolyte layer 104, a counter electrode (positive electrode) 105, a counter substrate 106, a sealing member 107, and the like.

As the semiconductor electrode layer 103, a porous layer in which fine particles of a metal oxide semiconductor such as titanium oxide, TiO₂ are sintered is often used, and the photosensitizing dye is supported on the surfaces of the fine particles constituting the semiconductor electrode layer 103. The electrolyte layer 104 fills between the semiconductor electrode layer 103 and the counter electrode 105, and contains an organic electrolytic solution that includes a redox species (redox pair) such as I⁻/I³⁻ or the like. The counter electrode 105 is constituted by a platinum layer 105b and the like and is formed on the counter substrate 106.

When light enters, the dye-sensitized photovoltaic device 100 operates as a cell in which the counter electrode 105 is a positive electrode and the semiconductor electrode layer 103 is a negative electrode. The principle thereof is as follows.

When a photosensitizing dye absorbs photons that have passed through the transparent substrate 101 and the transparent conductive layer 102, electrons in the photosensitizing dye are excited from a ground state (HOMO) to an excited state (LUMO). The electrons in the excited state are extracted into a conduction band of the semiconductor electrode layer 103 through electrical coupling between the photosensitizing dye and the semiconductor electrode layer 103 and reach the transparent conductive layer 102 by passing through the semiconductor electrode layer 103.

On the other hand, the photosensitizing dye that lost electrons receives electrons by the following reaction from a reductant, e.g., iodide ions I⁻, in the electrolyte layer 104:

2I⁻→I₂+2e⁻

I₂+I⁻→I³⁻

so as to generate an oxidant, e.g., triiodide ions I³⁻ (I₂ and I⁻ combined), in the electrolyte layer 104. The generated oxidant reaches the counter electrode 105 by diffusion and receives electrons from the counter electrode 105 through the following counter reaction of the reaction described above, thereby returning to the original reductant:

I³⁻→I₂+I⁻

I₂+2e⁻→2I⁻

Electrons sent out to an external circuit from the transparent conductive layer 102 do electrical work in the external circuit and return to the counter electrode 105. In this manner, optical energy is converted to electrical energy without leaving any traces in the photosensitizing dye or the electrolyte layer 104.

The dye-sensitized photovoltaic device 100 described above has the electrolyte layer 104 in a liquid form and is a type of so-called wet devices. In general, a wet functional device has a structure in which two substrates respectively provided with electrodes are arranged to oppose each other and a functional substance in a liquid form is enclosed in the gap therebetween. In the production process therefor, it is a general practice that after peripheral portions of the two substrates arranged to oppose each other are joined in advance with the sealing member 107 such as an adhesive or the like, a functional substance in a liquid form is injected through a liquid injection port 108 formed separately, and then the liquid injection port 108 is sealed with an adhesive layer 109 and an end seal 110.

The thickness of such a functional device is mainly the thickness of the substrates. Thus, a functional device having two substrates has a disadvantage of a large thickness compared to a functional device having only one substrate. For example, in a typical dye-sensitized solar cell, the thickness of one substrate is about 1.1 mm or more, but the thickness of the functional device as a whole is as large as 2.3 mm or more, a large proportion of which is occupied by the thickness of the two substrates.

In recent years, thickness reduction and weight reduction of mobile appliances are progressing, and functional devices mounted therein are also required to achieve thickness reduction and weight reduction. In the case where the thickness of a functional device including two substrates is to be reduced, a solution conceived first is to decrease the thickness of substrates. However, a hard and not readily deformable substrate, such as a glass substrate, undergoes a decrease in strength by thickness reduction and thereby becomes difficult to handle. Thus, thickness reduction of functional devices via thickness reduction of substrates is about to reach its limit. As functional devices that use two substrates known in the art, there are displays using liquid crystal or the like, batteries, capacitors, and the like in addition to the dye-sensitized photovoltaic devices.

The major point that determines the lifetime of a functional device having a functional substance in a liquid form is the sealing technology. As shown in FIG. 6, it is a general practice to conduct end sealing at the surfaces or end surfaces of the substrates; however, in such a case, a protruded portion is created by the end seal 110 at the surfaces or end surfaces of the substrates, thereby obstructing thickness reduction. Moreover, in the case where the strength of the end seal 110 is not sufficient, leakage easily occurs, which is one of the factors that shorten the lifetime of the functional device. Moreover, it takes a long time to inject a functional substance through the narrow liquid injection port 108, which is one of the factors that decrease the productivity.

The present invention has been made under the circumstances described above and aims to provide a functional device suitable for a dye-sensitized solar cell or the like and having a structure fit for thickness reduction, and a method for making the device with a high productivity.

### DISCLOSURE OF INVENTION

That is, the present invention relates to a functional device in which a counter electrode is provided between a base member provided with an electrode and a flexible member arranged to oppose the base member, the counter electrode facing the electrode; and a functional substance is disposed between the electrode and the counter electrode.

It also relates to a method for making a functional device in which a counter electrode is provided between a base member provided with an electrode and a flexible member arranged to oppose the base member, the counter electrode facing the electrode and a functional substance is disposed between the electrode and the counter electrode, wherein:

the functional substance is enclosed by joining the base member to the flexible member at a peripheral portion, or

the entirety or a part of the surface of the base member opposite to the electrode-provided side is covered with a connected flexible member connected to the flexible member and the functional substance is enclosed by first joining of the base member to the flexible member and/or the connected flexible member at a peripheral portion and/or by second joining of the flexible member to the connected flexible member at a peripheral portion,

the method comprising:

leaving, unjoined, a part of a joint of the joining or a part of a joint of the first joining and the second joining before introduction of the functional substance so as to function as an introduction port for the functional substance, and, after the introduction of the functional substance, joining the part.

In the functional device of the present invention, the counter substrate 106 (see FIG. 6) provided in the related art is replaced by the flexible member. A known substrate, such as a glass substrate, which is hard and not readily deformable undergoes a decrease in strength by thickness reduction and thereby becomes significantly difficult to handle due to cracking of the substrate or the like, resulting in a decrease in production yield. In contrast, the flexible member does not undergo cracking and thus become significantly difficult to handle despite thickness reduction. Thus, the counter substrate can be replaced by the film-shaped flexible member without decreasing the production yield, and the thickness of the functional device can be significantly reduced compared to the related art.

The method for making the functional device of the present invention is a method for making the functional device of the present invention described above in which:

the functional substance is enclosed by joining the base member to the flexible member at a peripheral portion, or

the entirety or a part of the surface of the base member opposite to the electrode-provided side is covered with a connected flexible member connected to the flexible member, and the functional substance is enclosed by first joining of the base member to the flexible member and/or the connected flexible member at a peripheral portion and/or by second joining of the flexible member to the connected flexible member at a peripheral portion.

According to this functional device, the functional substance is enclosed by the joining or the first joining and/or the second joining by utilizing the flexibility of the flexible member. During this process, a part of a joint of the joining or a part of a joint of the first joining and the second joining before introduction of the functional substance is left unjoined so as to function as an introduction port for the functional substance, and, after the introduction of the functional substance, the part is joined. Thus, the introduction port having a large opening area can be used to inject the functional substance, the functional substance can be rapidly introduced into the functional device, and the functional device can be produced with high productivity.

### BRIEF DESCRIPTION OF DRAWINGS

FIG. 1 includes a cross-sectional view (a) and a plan view (b) showing the structure of a dye-sensitized photovoltaic device according to a first embodiment of the present invention.

FIG. 2 includes plan views showing the flow of a process for enclosing the film-shaped counter electrode of the dye-sensitized photovoltaic device.

FIG. 3 includes a cross-sectional view (a) and a plan view (b) showing the structure of a dye-sensitized photovoltaic device according to a second embodiment of the present invention.

FIG. 4 includes a cross-sectional view (a) and a plan view (b) showing the structure of a dye-sensitized photovoltaic device according to modification 2 of the device.

FIG. 5 is a graph showing retention rate of photoelectric conversion efficiency of dye-sensitized photovoltaic devices of Examples 1 and 2 based on the present invention and Comparative Example 1.

FIG. 6 is a cross-sectional view showing the structure of a typical dye-sensitized photovoltaic device known in the art.

### BEST MODES FOR CARRYING OUT THE INVENTION

In a functional device of the present invention, it is preferable that the functional substance be enclosed by joining the base member and the flexible member to each other at a peripheral portion. This form is simple in structure and can be deemed as a basic form of the wet device based on the present invention.

Alternatively, the entirety or a part of the surface of the base member opposite to the electrode-provided side is preferably covered with a connected flexible member connected to the flexible member, and the functional substance is preferably enclosed by first joining of the base member to the flexible member and/or the connected flexible member at a peripheral portion and/or by second joining of the flexible member to the connected flexible member at a peripheral portion. The connected flexible member may be integral with the flexible member or may be a component separate from the flexible member but connected to the flexible member by bonding. In this form, the region of the electrode-side surface of the base member used for joining can be reduced, the region used for exhibiting functions can be increased, and the electrode-side surface of the base member can be effectively utilized.

In all forms, the flexible member and the connected flexible member are, as a packaging member, preferably composed of a material having a high capacity of suppressing movements of solvents, gasses, and/or water between the functional substance and outside environment. This is important for maintaining the performance and extending the lifetime of the functional device.

Furthermore, the joining or the first joining and the second joining are preferably formed by heat-sealing, thermosetting, or ultraviolet curing of an adhesive member. As with the flexible member and the connected flexible member described above, a sealing member used for the joining is preferably composed of a material having a high capacity of suppressing movements of solvents, gasses, and/or water between the functional substance and outside environment.

As described above, in the functional device of the present invention, the sealing structure can be configured not to include an end seal by utilizing the flexibility of the flexible member. As a result, the protruded portion formed by the end seal is eliminated, and thickness reduction is advantageously achieved. Moreover, there is no risk of shortening of the lifetime of the functional device by leakage caused by insufficient strength of the end seal, and a functional device having high long-term stability can be provided.

Moreover, the counter electrode is preferably arranged without being fixed onto the flexible member. In this manner, the flexible member no longer needs to support the counter electrode. Thus, there are advantages that the choice of the shape and material of the flexible member is widened and the production steps are simplified.

The base member is preferably composed of a light-transmitting material so that the device is configured to be a device having a photoelectric conversion function.

In this case, in order reduce the region of the electrode-side surface of the base member used for joining and to increase the region used for exhibiting functions, the entirety or a part of a light-incident-side surface of the base member is preferably covered with a light-transmitting connected flexible member connected to the flexible member, as described earlier. Also, the functional substance is preferably enclosed by first joining of the base member to the flexible member and/or the light-transmitting connected flexible member at a peripheral portion and/or by second joining of the flexible member to the light-transmitting connected flexible member at a peripheral portion. As described earlier, the flexible member and the connected light-transmitting flexible member may be integral or separate components.

Furthermore, configuration into a dye-sensitized photovoltaic device is preferable in which a semiconductor electrode layer supporting a photosensitizing dye is formed as the electrode at a light-transmitting-side of the base member, an electrolyte layer is provided as the functional substance, electrons of the photosensitizing dye excited by light absorption are extracted to the semiconductor electrode layer, and the photosensitizing dye that lost the electrons is reduced with a reductant in the electrolyte layer.

In a method for making a functional device according to the present invention, the joining or the first joining and the second joining are preferably formed by heat-sealing, thermosetting, or ultraviolet curing of an adhesive member. As described earlier, in the joining, as with the flexible member and the connected flexible member described above, a sealing member used is preferably composed of a material having a high capacity of suppressing movements of solvents, gasses, and/or water between the functional substance and outside environment.

Examples in which functional devices of the present invention are configured as dye-sensitized photovoltaic devices will now be specifically described in detail with reference to drawings on the basis of embodiments of the present invention.

### First Embodiment

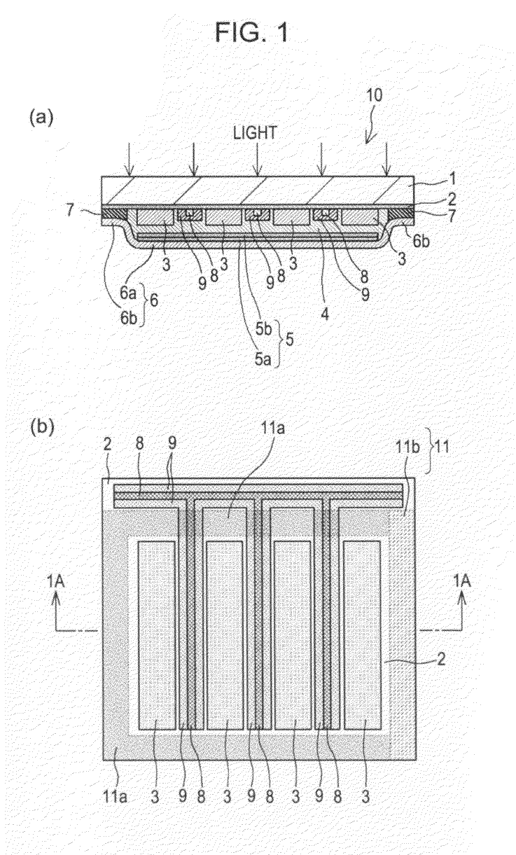

FIG. 1 includes a cross-sectional view (a) and a plan view (b) showing the structure of a dye-sensitized photovoltaic device 10 according to a first embodiment. Note that the cross-sectional view (a) is a cross-sectional view taken at the position shown by line 1A-1A in the plan view (b). In the plan view (b), only components formed on a transparent substrate 1 are depicted for easy recognition, and the position of a joint 11 between a film-shaped packaging member 6 and the transparent substrate 1 is surrounded and marked by dotted lines.

The dye-sensitized photovoltaic device 10 mainly corresponds to claim 1 and claim 2, and is constituted by the transparent substrate 1 formed of glass or the like, a transparent conductive layer 2 formed of FTO (fluorine-doped tin(IV) oxide, SnO₂) or the like, semiconductor electrode layers 3 (negative electrodes) supporting a photosensitizing dye, an electrolyte layer 4, a film-shaped counter electrode (positive electrode) 5, a film-shaped packaging member 6, a sealing member 7, power-collecting wiring 8, a wiring protecting layer 9, and the like. The transparent substrate 1, the semiconductor electrode layers 3, the electrolyte layer 4, the film-shaped counter electrode 5, and the film-shaped packaging member 6 respectively correspond to the base member, the electrode, the functional substance, the counter electrode, and the flexible member described above.

The semiconductor electrode layers 3 are porous layers in which fine particles of a metal oxide semiconductor such as titanium oxide, TiO₂ are sintered, and a photosensitizing dye is supported on surfaces of the fine particles constituting the semiconductor electrode layers 3. The electrolyte layer 4 is disposed between the semiconductor electrode layers 3 and the film-shaped counter electrode 5, and contains an organic electrolytic solution containing a redox species (redox pair) such as I⁻/I³⁻ or the like.

In the porous layers constituting the semiconductor electrode layers 3, the area of surfaces of constituent fine particles facing voids inside the porous layers is about several thousands times larger than the area of the outer surfaces of the porous layers (projected area). Thus, supporting of the photosensitizing dye and progress of electrode reaction in the semiconductor electrode layers 3 mainly take place on the constituent fine particle surfaces facing voids inside the porous layers. Thus, in this specification, in a material in which microstructures are formed such as the porous layers, the total surface area of the material forming the microstructure is referred to as “actual surface area” so as to distinguish it from the area of the outer surfaces of the material (projected area). In order to decrease the resistance of the path through which electrons are extracted and improve the power-collecting efficiency, the semiconductor electrode layers 3 are formed in stripes (strips) between which the power-collecting wiring 8, which is patterned, is formed on the transparent conductive layer 2. There is no particular limitation on the conductive material that forms the power-collecting wiring 8, but a highly conductive metal such as silver or carbon is preferred. In order to enhance corrosion resistance of the power-collecting wiring 8, the wiring protecting layer 9 composed of a resin or the like is formed to cover the power-collecting wiring 8.

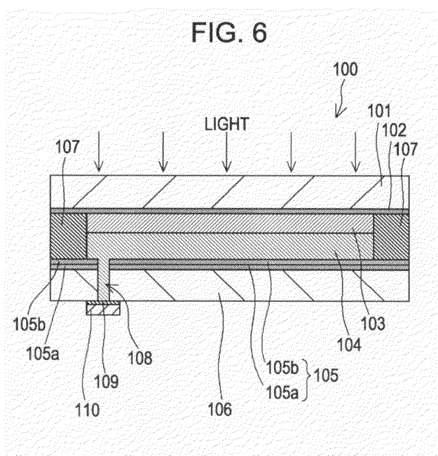

In the dye-sensitized photovoltaic device 10, the counter substrate 106 (see FIG. 6) which has been provided in the related art is replaced with the film-shaped packaging member 6; hence, the transparent substrate 1 is the only substrate constituting the device and significant thickness reduction is achieved compared with the known dye-sensitized photovoltaic device 100 that uses two substrates.

Furthermore, as described below, due to the flexibility of the film-shaped packaging member 6, the sealing structure has a structure that does not use the end seal 110. As a result, the protruded portion formed by the end seal 110 is eliminated, which is advantageous for thickness reduction. Moreover, there is no risk of shortening of the lifetime of the dye-sensitized photovoltaic device 10 by leakage caused by insufficient strength of the end seal 110, and the device is rendered excellent long-term stability.

The material of the film-shaped packaging member 6 is not particularly limited, but a material that has high barrier property of suppressing passage of the solvent contained in the electrolyte layer 4 and gas and water in the atmosphere and excellent resistance to organic solvents and heat is preferred. If necessary, a composite film in which a plurality of layers composed of materials with different properties such as a dense metal layer represented by aluminum, a protective layer, or an adhesive layer are stacked may be used.

As shown in (a) of FIG. 1, the film-shaped packaging member 6 is preferably formed to include a main portion 6a having a cross-sectional shape of a short trapezoid and an edge portion 6b that slightly extends outward. The transparent substrate 1 having a surface on which the transparent conductive layer 2 is formed is joined to the film-shaped packaging member 6 by bonding the joint 11 in the peripheral portion of the transparent substrate 1 to the edge portion 6b of the film-shaped packaging member 6 with the sealing member 7. As an alternative method, side surfaces of the transparent substrate 1 may be joined to the peripheral portion of the film-shaped packaging member 6.

As the method for bonding using the sealing member 7, there are a method of heat sealing a polymer layer having an adhesive functional group such as an acidic functional group, an ester bond, an ether bond, and a hydroxyl group (hydroxy group); and a method for bonding with an adhesive such as various thermosetting adhesives, UV-curable adhesives, two-liquid mixing type adhesives, and the like. The sealing member 7 having high adhesiveness and high barrier property of suppressing passage of the solvent contained in the electrolyte layer 4 and gasses and water in the atmosphere is used.

Because the counter substrate 106 is replaced with the film-shaped packaging member 6, the change is made so that the film-shaped counter electrode 5 has a shape of a film disposed unfixed on the counter substrate. In this manner, the film-shaped packaging member 6 no longer needs to support the counter electrode, and thus the choice of the shape and material of the film-shaped packaging member 6 is widened and the production steps are simplified.

The film-shaped counter electrode 5 is the same as the known counter electrode 105 or the like in all other points. That is, although there is no particular limitation on the film-shaped counter electrode 5, it is preferable that a catalyst layer 5b, e.g., a platinum layer, having a catalytic effect on reduction reaction that occurs on the counter electrode 5 be formed on a surface contacting the electrolyte layer 4. As the material of an underlayer 5a, any conductive substance that can be formed into a film can be used, but a material that is stable electrochemically is preferred. Alternatively, an insulating substance may also be used as long as a conductive layer is formed at the side in contact with the electrolyte layer 4.

To be more specific, a layer formed by forming, by sputtering or the like, the catalyst layer 5b such as a platinum layer on a metal foil such as niobium which is the underlayer 5a is preferred. If the catalyst layer 5b itself has electrical conductivity, the film-shaped counter electrode 5 may be a film constituted by a single layer of the catalyst layer itself, or may be formed by forming the catalyst layer 5b by a low-temperature process such as a puttering method vapor deposition method on the underlayer 5a such as a plastic film.

In order to enhance the catalytic effect on the reduction reaction at the film-shaped counter electrode 5, microstructures are preferably formed in the surface of the film-shaped counter electrode 5 in contact with the electrolyte layer 4 so as to increase the actual surface area. For example, when the catalyst layer 5b is a platinum layer, it is preferably formed into a platinum black state. Platinum black can be formed by an anodization method of platinum, a chloroplatinic acid treatment, or the like.

The counter electrode need not have an independent film shape and may be fixed onto the film-shaped packaging member 6. Moreover, usually, the film-shaped counter electrode 5 and the film-shaped packaging member 6 do not have to transmit light and thus opaque materials may be used as the materials thereof. However, if necessary, a metal, such as platinum, having a high redox catalytic effect may be laid out as wiring on the a transparent conductive film or the surface may be treated with chloroplatinic acid so that the film-shaped counter electrode 5 serves as a transparent counter electrode and a light-transmitting material may be used in the film-shaped packaging member 6 to thereby allow transmission of light.

A method for making the dye-sensitized photovoltaic device 10 is not particularly limited, but as described below, preferred is a method in which a part 11b of the joint 11 between the transparent substrate 1 and the film-shaped packaging member 6 is left unjoined so that it can serve as an introduction port of the electrolytic solution before introduction of the electrolytic solution, and this unjoined portion is joined after the introduction of the electrolytic solution.

That is, in the case where the electrolyte is in a liquid form or an electrolyte in a liquid form is introduced and gelled in the dye-sensitized photovoltaic device 10, the transparent conductive layer 2 and the semiconductor electrode layer 3 supporting the photosensitizing dye are layered on the transparent substrate 1, as in the related art.

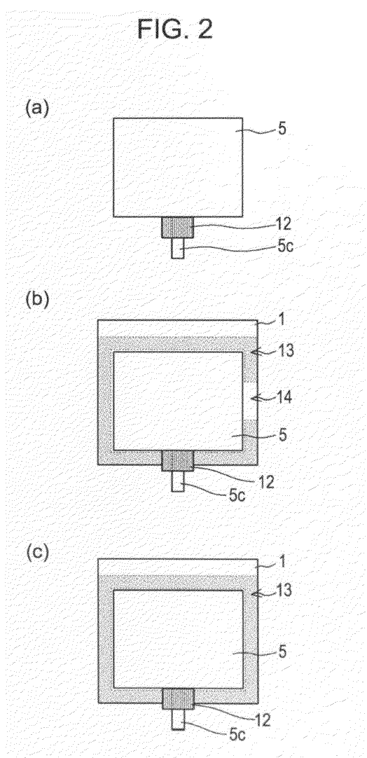

Next, as shown in FIG. 1(a) and FIG. 1(b), the film-shaped counter electrode 5 is placed on the semiconductor electrode layers 3 with the catalyst layer 5b side opposing, and then the film-shaped packaging member 6 is further overlaid. A joint 11a at the peripheral portion of the transparent substrate 1 on which the transparent conductive layer 2 is formed is bonded to the edge portion 6b of the film-shaped packaging member 6 with the sealing member 7. During this process, the part 11b of the joint 11 is left unjoined to form an introduction port for introducing the electrolytic solution. Note that, the joining part 11b is provided in a region where an extraction portion of the power-collecting wiring 8 and an extraction portion 5c (refer to FIG. 2) from the film-shaped counter electrode 5 are absent so that the extraction portions of the wiring 8 and the electrode 5 are sealed at this stage.

Next, the electrolytic solution is introduced into the dye-sensitized photovoltaic device 10 through an introduction port, which is the gap between the unjoined transparent substrate 1 and film-shaped packaging member 6 at the joint 11b, so as to sufficiently impregnate the semiconductor electrode layer 3. Subsequently, the joint 11b is joined under a reduced pressure to completely seal the interior of the device 10.

In this manner, the electrolytic solution can be rapidly introduced to the interior of the device 10 through the introduction port having a large opening area, and the dye-sensitized photovoltaic device 10 can be produced with high productivity.

In the case of a gel electrolyte, the gel electrolyte is applied on the semiconductor electrode layers 3 so that the semiconductor electrode layers 3 are sufficiently impregnated with the electrolytic solution, the film-shaped counter electrode 5 and the film-shaped packaging member 6 are then sequentially overlaid, and the joints of the transparent substrate 1 and the film-shaped packaging member 6 are bonded with the sealing member 7 under a reduced pressure.

FIG. 2 includes plan views showing the flow of a process for enclosing the film-shaped counter electrode 5 in the dye-sensitized photovoltaic device 10. Note that in FIG. 2(b) and FIG. 2(c), only the transparent substrate 1, the film-shaped counter electrode 5, and a heat sealing film 12 are illustrated for easy recognition, and the position of the joined portion is marked with hatching.

As shown in FIG. 2(a), the extraction portion 5c is provided to the film-shaped counter electrode 5, and the extraction portion 5c includes a material for sealing, e.g., the heat sealing film 12. In order to enclose the film-shaped counter electrode 5 in the dye-sensitized photovoltaic device 10, as shown in FIG. 2(b), the film-shaped counter electrode 5 is placed on the transparent substrate 1 and the film-shaped packaging member 6 is further overlaid thereon (omitted from the drawing). While leaving an unjoined portion 14 intact, the peripheral portion of the transparent substrate 1 is bonded to the edge portion 6b of the film-shaped packaging member 6 at a joint 13 by using a heat sealer or the like. During this process, the film-shaped counter electrode extraction portion 5c is heat joined onto the transparent substrate 1 along with the film-shaped packaging member 6 (omitted from the drawing). Next, after the electrolytic solution is introduced through the unjoined portion 14, the unjoined portion 14 is joined. When sealed under a reduced pressure, the packaging film adheres onto the transparent substrate 1 and the film-shaped counter electrode 5 is retained in a state of adhering onto the transparent substrate 1.

When light enters, the dye-sensitized photovoltaic device 10 operates as a cell in which the film-shaped counter electrode 5 is a positive electrode and the semiconductor electrode layer 3 is a negative electrode. The principle thereof is not different from that of the known dye-sensitized photovoltaic device 100, which is as follows.

When a photosensitizing dye absorbs photons that have passed through the transparent substrate 1 and the transparent conductive layer 2, electrons in the photosensitizing dye is excited from a ground state (HOMO) to an excited state (LUMO). The electrons in the excited state are extracted into a conduction band of the semiconductor electrode layer 3 through electrical coupling between the photosensitizing dye and the semiconductor electrode layer 3 and reach the transparent conductive layer 2 by passing through the semiconductor electrode layer 3.

On the other hand, the photosensitizing dye that lost electrons receives electrons by the following reaction from a reductant, e.g., I⁻, in the electrolyte layer 4:

2I⁻→I₂+2e⁻

I₂+I⁻→I³⁻

so as to generate an oxidant, e.g., I³⁻, in the electrolyte layer 4. The generated oxidant reaches the film-shaped counter electrode 5 by diffusion and receives electrons from the film-shaped counter electrode 5 through the following counter reaction of the reaction described above, thereby returning to the original reductant:

I³⁻→I₂+I⁻

I₂+2e⁻→2I⁻

Electrons sent out to an external circuit from the transparent conductive layer 2 do electrical work in the external circuit and then return to the film-shaped counter electrode 5. In this manner, optical energy is converted to electrical energy without leaving any traces in the photosensitizing dye or the electrolyte layer 4.

The dye-sensitized photovoltaic device of this embodiment can be fabricated into various shapes depending on the usage, and the shape and form thereof are not particularly limited. For example, for the purposes of protection of the substrate surface, antifouling, antireflection, UV cut, and the like, a film-shaped packaging member not involved in the sealing of the interior of the dye-sensitized photovoltaic device may be separately provided at the light incident side of the transparent substrate 1.

The dye-sensitized photovoltaic device 10 is the same as the known dye-sensitized photovoltaic device 100 or the like in all parts except that the counter substrate 106 of the known art is replaced with the film-shaped packaging member 6 to achieve thickness reduction and that the sealing structure is changed. There parts are described below in detail.

The transparent substrate 1 is not particularly limited as long as the material and shape allow light to be easily transmitted, and various substrate materials can be used. In particular, a substrate material having a high visible light transmittance is preferred. Moreover, a material that has high barrier property of suppressing water and gas entering from outside into the dye-sensitized photovoltaic device 10 and exhibits excellent resistance to solvents and weather is preferred. Specific examples thereof include transparent inorganic substrates such as quartz, sapphire, and glass; and transparent plastic substrates such as polyethylene terephthalate, polyethylene naphthalate, polycarbonate, polystyrene, polyethylene, polypropylene, polyphenylene sulfide, polyvinylidene fluoride, acetyl cellulose, phenoxy bromide, aramids, polyimides, polystyrenes, polyarylates, polysulfones, polyolefins, and the like. The thickness of the transparent substrate 1 is not particularly limited and may be adequately selected by taking into account the light transmittance, the barrier property of isolating the interior of the dye-sensitized photovoltaic device 10 from the exterior, the mechanical strength, and the like. The transparent conductive layer 2 serving as the electron extraction path is formed on the surface of the transparent substrate 1. The transparent conductive layer 2 preferably has as small sheet resistance as possible, in particular, preferably 500 Ω/cm² or less and more preferably 100 Ω/cm² or less. A known material can be used as the material for forming the transparent conductive layer 2, and specifically, indium-tin complex oxide (ITO), fluorine-doped tin (IV) oxide, SnO₂(FTO), antimony-doped tin(IV) oxide, SnO₂(ATO), and tin(IV) oxide, SnO₂ and the like are named. The material is not limited to these, and a combination of two or more of these compounds can be used.

Porous layers in which semiconductor fine particles are sintered are often used as the semiconductor electrode layers 3. Compound semiconductor materials, perovskite-structure materials, and the like in addition to elemental semiconductor materials represented by silicon can be used as the semiconductor material constituting the semiconductor electrode layers 3. These semiconductor materials are preferably n-type semiconductor materials in which conduction band electrons become carriers by photoexcitation to generate anode current. Specific examples thereof are titanium oxide, TiO₂, zinc oxide, ZnO, tungsten oxide, WO₃, niobium oxide, Nb₂O₅, strontium titanate, SrTiO₃, and tin oxide, SnO₂; and anatase-type titanium oxide, TiO₂ is particularly preferred. Moreover, the types of semiconductor materials are not limited to these, and these may be used alone or as a mixture or a complex of two or more. Furthermore, the semiconductor fine particles can take various forms according to needs, such as granular, tubular, bar-shaped, etc.

The film forming method for the semiconductor electrode layers 3 is not particularly limited. Considering the physical properties, convenience, manufacture cost, and the like, a wet film forming method is preferred, and a method including preparing a paste-like dispersion in which a powder or sol of semiconductor fine particles is homogeneously dispersed in a solvent such as water and applying or printing the dispersion on the transparent substrate 1 on which the transparent conductive layer 2 is formed is preferred. The coating method and the printing method are not particularly limited and can be conducted by a known method. For example, a dip method, a spray method, a wire bar method, a spin-coating method, a roller coating method, a blade coating method, a gravure coating method, and the like can be employed as the coating method. As the wet printing method, a letter press method, an offset printing method, a gravure printing method, an intaglio printing method, a rubber plate printing method, a screen printing method, and the like can be used.

In the case of using titanium oxide, the crystal type thereof is preferably anatase having excellent photocatalytic activity. The anatase-type titanium oxide used may be a commercially available product in a powder, sol, or slurry form or may be prepared by a known method, such as hydrolysis of titanium oxide alkoxide, so that the particle size is appropriate. In using a commercially available powder, it is preferable to eliminate secondary aggregation of particles, and it is preferable to pulverize particles by using a mortar, a ball mill, or the like during preparation of a paste-form dispersion. At this step, in order to prevent re-aggregation of the particles after elimination of the secondary aggregations, acetyl acetone, hydrochloric acid, nitric acid, a surfactant, a chelating agent, or the like may be added to the paste-form dispersion. Moreover, in order to increase the viscosity of the paste-form dispersion, a polymer such as polyethylene oxide, polyvinyl alcohol, or the like, and various thickners such as cellulose thickners can also be added to the paste-form dispersion.

The particle size of the semiconductor fine particles is not particularly limited but is preferably 1 to 200 nm and more preferably 5 to 100 nm in terms of average particle size of primary particles. It is also possible to improve the quantum yield by mixing particles larger than the semiconductor fine particles to thereby scatter incident light. In such a case, the average size of the particles to be mixed separately is preferably 20 to 500 nm.

The semiconductor electrode layers 3 preferably have a large actual surface area including the fine particle surfaces facing the voids inside the porous layers so that as much photosensitizing dye as possible can be adsorbed. In this respect, the actual surface area in the state in which the semiconductor electrode layer 3 is formed on the transparent conductive layer 2 is preferably at least 10 times, and more preferably at least 100 times, the area of the outer surfaces of the semiconductor electrode layer 3 (projected area). Although there is no upper limit for this ratio, it is usually about 1000 times.

In general, with an increase in thickness of the semiconductor electrode layer 3 and an increase in the number of semiconductor fine particles contained per unit projected area, the actual surface area increases and the quantity of the dye that can be supported per unit projected area increases, thereby increasing the light absorption ratio. On the other hand, with the increase in thickness of the semiconductor electrode layer 3, electrons that have migrated from the photosensitizing dye to the semiconductor electrode layer 3 travel a larger distance to reach the transparent conductive layer 2 by diffusion, and thus, the loss of electrons caused by recombination of charges in the semiconductor electrode layer 3 also increases. Accordingly, there is a preferable thickness for the semiconductor electrode layer 3; however, the thickness is usually 0.1 to 100 μm, preferably 1 to 50 μm, and particularly preferably 3 to 30 μm.

The semiconductor electrode layers 3 are preferably sintered after formation of the semiconductor fine particle layer on the transparent conductive layer 2 by an application method or a printing method so as to electrically couple the fine particles to one another, improve the mechanical strength of the semiconductor electrode layer 3, and improve the adhesiveness to the transparent conductive layer 2. The range of sintering temperature is not particularly limited, but increasing the temperature excessively may increase the electrical resistance of the transparent conductive layer 2 and may even lead to melting of the transparent conductive layer 2. Thus, usually, the temperature is preferably 40° C. to 700° C. and more preferably 40° C. to 650° C. Moreover, the sintering time is not particularly limited but is usually about 10 minutes to about 10 hours.

After sintering, in order to increase the surface area of the semiconductor fine particles or increasing the necking between semiconductor fine particles, for example, chemical plating using an aqueous titanium tetrachloride solution, a necking treatment using an aqueous titanium trichloride solution, or a dip treatment by semiconductor ultrafine particle sol having a diameter of 10 nm or less may be conducted. In the case where a plastic substrate is used as the transparent substrate 1 that supports the transparent conductive layer 2, it is possible to form the semiconductor electrode layer 3 on the transparent conductive layer 2 by using a paste-form dispersion containing a binder and to press-bond the semiconductor electrode layer 3 onto the transparent conductive layer 2 by heat pressing.

The photosensitizing dye supported by the semiconductor electrode layers 3 is not particularly limited as long as it has a sensitizing effect. Examples thereof include xanthene dyes such as rhodamine B, rose bengal, eosin, and erythrocin; cyanine dyes such as merocyanine, quinocyanine, and cryptocyanine; basic dyes such as phenosafranine, Cabri blue, thiocine, and methylene blue; other azo dyes; porphyrin compounds such as chlorophyll, zinc porphyrin, magnesium porphyrin; phthalocyanine compounds; coumarin compounds; bipyridine or terpyridine complexes of ruthenium (Ru); anthraquinone dyes; polycyclic quinone dyes; and squalirium dyes. Among these, bipyridine complexes of ruthenium (Ru) are preferable as the photosensitizing dye due to their high quantum yield. However, the photosensitizing dye is not limited to these, and one or combination of two or more of these can be used.

The method for rendering the semiconductor electrode layers 3 to support the photosensitizing dye is not particularly limited; however, for example, it is preferable to dissolve a dye in a solvent, e.g., alcohols, nitriles, nitromethane, halogenated hydrocarbon, ethers, dimethyl sulfoxide, amides, N-methylpyrrolidone, 1,3-dimethyl imidazolidinone, 3-methyl oxazolidinone, esters, carbonates, ketones, hydrocarbon, and water and immerse the semiconductor electrode layer 3 in this dye solution; or to apply the dye solution onto the semiconductor electrode layer 3 so that the photosensitizing dye is adsorbed to the semiconductor electrode layer 3. Moreover, in order to reduce associations of the dyes to each other, a deoxycholic acid or the like may be added to the dye solution.

After the dye is adsorbed, the surfaces of the semiconductor electrode layers 3 may be treated with an amine. Examples of the amine are pyridine, 4-tert-butyl pyridine, polyvinyl pyridine, and imidazole compounds. These may be used as they are if the amines are liquid or may be used by being dissolved in organic solvents.

As the electrolyte layer 4, an electrolytic solution containing a redox system (redox pair) or an electrolyte in a gel or solid form can be used. In particular, as the electrolyte, a combination of iodine, 12 and a metal iodide salt or an organic iodide salt or a combination of bromine, Br₂ and a metal bromide salt or an organic bromide salt is used. The cation in the metal halide salt is lithium Li⁺, sodium Na⁺, potassium K⁺, cesium Cs⁺, magnesium Mg²⁺, calcium Ca²⁺, and the like and the cation in the organic halide is preferably a quaternary ammonium ions such as tetraalkylammonium ions, pyridinium ions, imidazolium ions, and the like. However, these examples are not limiting, and one or a combination of two or more of these may be used.

Other than these, examples of the electrolyte useable include a metal complex such as a combination of a ferrocyanate salt and a ferricyanate salt, a combination of ferrocene and a ferricinium ion, or the like; a sulfur compound such as a combination of sodium polysulfate, alkyl thiol, and alkyl disulfide; and a combination of a viologen dye, hydroquinone, and quinone.

Among these, an electrolyte in which iodine, 12 is combined with a quaternary ammonium compound such as lithium iodide, LiI, sodium iodide, NaI, imidazolium iodide, or the like is particularly preferred. The concentration of the electrolyte salt in the electrolytic solution is preferably 0.05 M to 5 M, more preferably 0.1 M to 3 M. The concentration of iodine I₂ or bromine Br₂ is preferably 0.0005 M to 1 M and more preferably 0.005 to 0.5 M. For the purpose of improving the open circuit voltage or short circuit current, various additives such as 4-tert-butyl pyridine or carboxylic acid may be added.

As the solvent in the electrolytic solution, water, alcohols, ethers, esters, carbonic acid esters, lactones, carboxylic acid esters, phosphoric acid triesters, heterocyclic compounds, nitrites, ketones, amides, nitromethane, halogenated hydrocarbon, dimethyl sulfoxide, sulfolane, N-methylpyrrolidone, 1,3-dimethyl imidazolidinone, 3-methyl oxazolidinone, hydrocarbons, and the like can be named. However, they are not limiting and one or a combination of two or more of these may be used. It is also possible to use, as a solvent, a room-temperature ionic liquid of a tetraalkyl-based, pyridinium-based, or imidazolium-based quaternary ammonium salt.

To reduce leakage of the electrolytic solution from the dye-sensitized photovoltaic device 10 or vaporization of the solvent in the electrolytic solution, a gelling agent, a polymer, a cross-linking monomer, a ceramic nanoparticle powder, or the like may be added to the constituents of the electrolyte by dissolution or dispersion so that the electrolyte can be used in a gel form. As for the ratio of the gelling material to the electrolyte constituents, the ion conductivity increases but the mechanical strength decreases as the amount of the electrolyte constituents increases. On the contrary, if the amount of the electrolyte constituents is excessively small, the mechanical strength is high but the ion conductivity decreases. Thus, the amount of the electrolyte constituents is preferably 50 to 99 mass % and more preferably 80 to 97 mass % of the gel electrolyte. Moreover, it is possible to realize an all-solid photosensitized photovoltaic device by mixing the electrolyte constituents, a plasticizer, and a polymer and then removing the plasticizer by evaporation.

### Second Embodiment

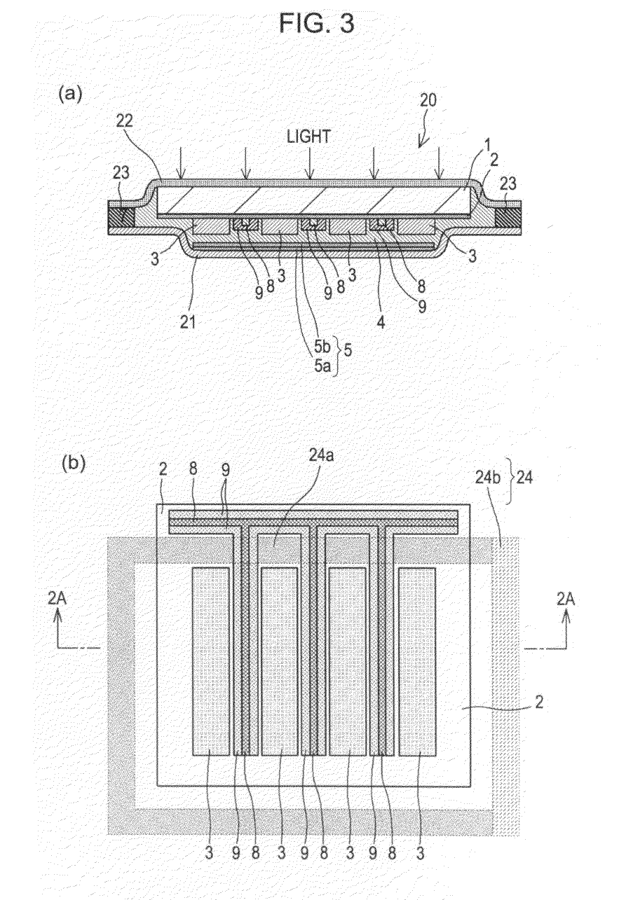

FIG. 3 includes a cross-sectional view (a) and a plan view (b) showing the structure of a dye-sensitized photovoltaic device 20 according to a second embodiment. Note that the cross-sectional view (a) is a cross-sectional view taken at the position shown by line 2A-2A in the plan view (b). In the plan view (b), only components formed on a transparent substrate 1 are depicted for easy recognition, and the position of a joint 24 of a film-shaped packaging member 21, the transparent substrate 1, and an light-incident-side film-shaped packaging member 22 is surrounded and marked by dotted lines.

The dye-sensitized photovoltaic device 20 mainly corresponds to claim 1 and claim 5, and is constituted by a transparent substrate 1 formed of glass or the like, a transparent conductive layer 2 formed of FTO (fluorine-doped tin(IV) oxide, SnO₂) or the like, semiconductor electrode layers 3 (negative electrodes) supporting a photosensitizing dye, an electrolyte layer 4, a film-shaped counter electrode (positive electrode)₅, a film-shaped packaging member 21, a sealing member 23, power-collecting wiring 8, a wiring protecting layer 9, the light-incident-side film-shaped packaging member 22, and the like. The film-shaped packaging member 21 and the light-incident-side film-shaped packaging member 22 respectively correspond to the flexible member and the connected flexible member described above.

In the dye-sensitized photovoltaic device 20, the light-incident-side film-shaped packaging member 22 is additionally provided at the light incident side of the transparent substrate 1; and as a result, the joint 24 for sealing the electrolyte layer 4 is formed not only between the transparent substrate 1 and the film-shaped packaging member 21 but also between the film-shaped packaging member 21 and the light-incident-side film-shaped packaging member 22 and between the transparent substrate 1 and the light-incident-side film-shaped packaging member 22. Since other portions are the same as those of the dye-sensitized photovoltaic device 10 of the first embodiment, only the differences are described with emphasis below to avoid redundancy.

This example shows the case in which the film-shaped packaging member 21, i.e., the flexible member, and the light-incident-side film-shaped packaging member 22, i.e., the connected flexible member, are separate components. In such a case, the light-incident-side film-shaped packaging member 22 and the transparent substrate 1 are joined entirely and become integral in the region where they overlap. As in the first embodiment, the film-shaped packaging member 21 is joined to the integrated transparent substrate 1 and the light-incident-side film-shaped packaging member 22 at the joint 24. In such a case, the light-incident-side film-shaped packaging member 22 can be considered as an extension of the transparent substrate 1. As shown in FIG. 3(b), joining of the film-shaped packaging member 21 to the integrated transparent substrate 1 and the light-incident-side film-shaped packaging member 22 mainly takes place on the light-incident-side film-shaped packaging member 22, which is an extension of the transparent substrate 1; thus, the substrate area of the transparent substrate 1 used for joining can be decreased, the substrate area of the transparent substrate 1 used for the photoelectric conversion can be increased, and the substrate surface of the transparent substrate 1 can be effectively utilized.

In the dye-sensitized photovoltaic device 20, since the film-shaped packaging member 21 and the light-incident-side film-shaped packaging member 22 are separate components, there is an advantage that the optimum material can be selected as the material of each component. For example, since this example is a photovoltaic device, the light-incident-side film-shaped packaging member 22 needs to have light-transmitting property. Moreover, it is also preferred that an adhesive member, an adhesive film, or the like for joining the transparent substrate 1 to the light-incident-side film-shaped packaging member 22 have light-transmitting property. Furthermore, it is possible to impart various functions, such as improving physical strength, preventing reflection, preventing fouling, cutting the ultraviolet and heat rays, and the like to the surface of the light-incident-side film-shaped packaging member 22 by surface treatment depending on the purpose. Also, since the film-shaped packaging member 21 need not have light-transmitting property, a material may be selected on the basis of the barrier property or resistance to organic solvents or heat as described above.

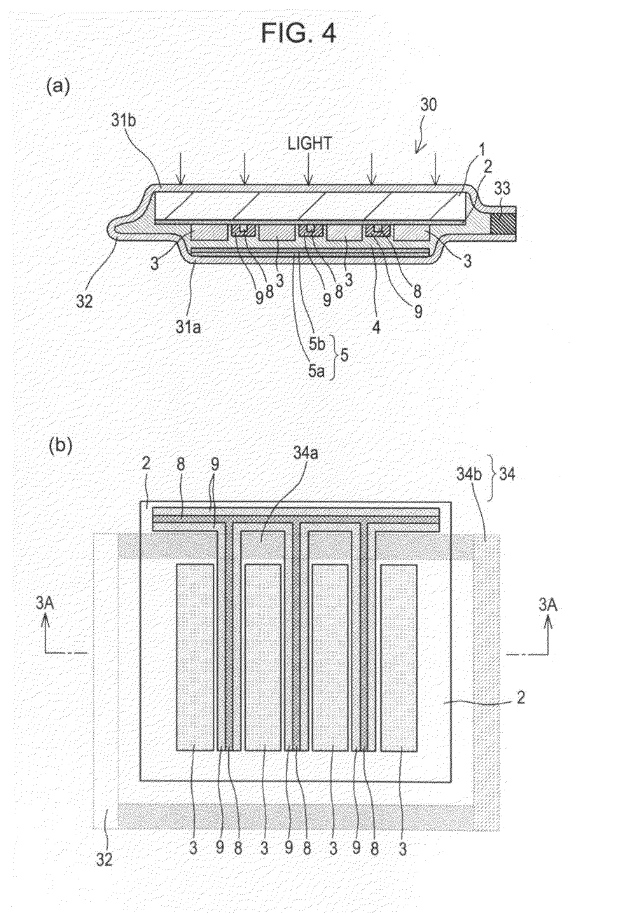

FIG. 4 includes a cross-sectional view (a) and a plan view (b) showing the structure of a dye-sensitized photovoltaic device 30 according to a modification of the second embodiment. Note that the cross-sectional view (a) is a cross-sectional view taken at the position shown by line 3A-3A in the plan view (b). In the plan view (b), only components formed on a transparent substrate 1 are depicted for easy recognition, and the position of a joint 34 of a film-shaped packaging member 31a, the transparent substrate 1, and a film-shaped packaging member 31b folded toward the light incident side is surrounded and marked by dotted lines.

This example shows the case where the flexible material and the connected flexible material are integral. That is, a first half portion, 31a, of a film-shaped packaging member 31 serves as the flexible member, and a second half portion, 31b, which is folded at a folding portion 32, serves as the connected flexible member. In comparison with the dye-sensitized photovoltaic device 20 shown in FIG. 3, the film-shaped packaging member 31b folded toward the light incident side is used instead of the light-incident-side film-shaped packaging member 22 and the rest of the structure is completely the same.

As in this example, in the case where the flexible member and the connected flexible member are composed of one material, the conditions required for the flexible member and the conditions required for the connected flexible member must be fulfilled by one material; hence, there are more limitations as to the choice of the material. However, since the joined portion can be reduced, there is a possibility that barrier property and resistance to organic solvent and heat can be improved.

The second embodiment is the same as the first embodiment except that the light-incident-side film-shaped packaging member 22 is additionally provided at the light incident side of the transparent substrate 1; thus, the same advantages and effects can be naturally achieved regarding common components.

In other words, in the dye-sensitized photovoltaic devices 20 and 30, the transparent substrate 1 is the only substrate constituting device, and thus, compared to the dye-sensitized photovoltaic device 100 of an existing type in which two substrates are used, significant thickness reduction is achieved. Moreover, since the sealing structure is configured so that the end seal 110 is not used, the device is advantageous in achieving thickness reduction and excellent long-term stability and productivity.

In the modification above, a structure in which part of the transparent substrate 1 is exposed to the exterior is shown as an example. Alternatively, the entirety of the transparent substrate 1 may be covered with a film-shaped packaging member. In such a case, the film-shaped packaging member may include a film-shaped packaging member and an light-incident-side film-shaped packaging member joined to each other at end portions as described in the second embodiment, or may be a film-shaped packaging member 31a folded in half so that the two halves may be joined to each other at end portions, as described in the modification of the second embodiment. In either case, as shown in FIG. 2, it is preferable to extract electrodes while maintaining hermetical seal by using a heat-sealing film or the like.

### EXAMPLES

Examples of the present invention will be described below in detail, but the present invention is not limited to these examples. In the examples, the dye-sensitized photovoltaic devices 10 and 20 respectively shown in FIGS. 1 and 3 were prepared as the functional devices of the present invention, and the maximum thickness and the photoelectric conversion efficiency were measured to conduct comparison with the dye-sensitized photovoltaic device 100 of the related art shown in FIG. 6.

### <Preparation of Dye-Sensitized Photovoltaic Device>

### Example 1

The dye-sensitized photovoltaic device 10 shown in FIG. 1 was prepared. A FTO layer as the transparent conductive layer 2 was formed on a transparent substrate 1, 32 mm×49 mm in size and 1.1 mm in thickness. As a titanium oxide, TiO₂, paste, i.e., the material for forming the semiconductor electrode layer 3, Ti-Nanoxide TSP produced by Solaronix was used. This TiO₂ paste was coated on the transparent conductive layer 2 by a screen printing method using a 150-mesh screen so as to form four semiconductor fine particle paste layers of stripe (strip) forms each 5 mm×40 mm in size. Subsequently, a silver fine particle layer 0.5 mm in width and 46 mm in length for forming the power-collecting wiring 8 was formed by a printing method on the transparent conductive layer 2 between the semiconductor fine particle paste layers.

Then TiO₂ fine particles and the silver fine particles were sintered on the transparent conductive layer 2 composed of FTO by retaining at 500° C. for 30 minutes. The porous layers composed of sintered titanium oxide fine particles were retained in a 0.05 M aqueous titanium tetrachloride solution at 70° C. for 30 minutes. After washing the titanium oxide porous layers, sintering was again conducted at 500° C. for 30 minutes to obtain the semiconductor electrode layers 3 and the power-collecting wiring 8. Subsequently, in order to enhance the corrosion resistance of the power-collecting wiring 8, a resin was coated on the silver wiring 8 to form the wiring protecting layer 9.

Next, cis-bis(isothiocyanato)-N,N-bis(2,2′-bipyridyl-4,4′-dicarboxylic acid)ruthenium(II) ditetrabutylammonium salt, which was a photosensitizing dye, was dissolved in a 1:1 (vol) solvent mixture of tert-butyl alcohol and acetonitrile so that the concentration was 0.3 mM to prepare a photosensitizing dye solution. The semiconductor electrode layers 3 were immersed in this photosensitizing dye solution for 24 hours at room temperature so that the surfaces of the TiO₂ fine particles constituting the semiconductor electrode layers 3 support the photosensitizing dye. Next, after an acetonitrile solution of 4-tert-butylpyridine and acetonitrile were sequentially used to wash the semiconductor electrode layers 3, drying was conducted while evaporating the solvent in a dark place.

On the other hand, as the film-shaped counter electrode 5, a platinum layer (the catalyst layer 5b) having a thickness of 1000 Å was formed by a sputtering method on one surface of a niobium foil (underlayer 5a) having a thickness of 0.05 mm. The film-shaped counter electrode 5 was arranged so that the platinum layer (catalyst layer 5b) side opposes the semiconductor electrode layer 3 of the transparent substrate 1, and the film-shaped packaging member 6, which was a three-layer film of polyethylene/aluminum/nylon formed to have a cross-sectional shape of a short trapezoid with the edge portion 6b, was overlaid thereon.

Next, the joint 11a at three sides of the peripheral portion of the transparent substrate 1 with the FTO layer 2 formed thereon was bonded to the edge portion 6b of the film-shaped packaging member 6 with a heat-sealing resin such as maleic anhydride-modified polyethylene or the like. At this stage, the film-shaped packaging member 6 was arranged so that the polyethylene layer of the three-layer film served as the bonding surface. Alternatively, a four-layer film of polyethylene/aluminum/polyethylene/polyethylene terephthalate may be used with the polyethylene layer serving as the bonding surface. The joint 11b at the remaining side of the peripheral portion of the transparent substrate 1 was left unjoined so as to form a port for introducing an electrolytic solution.

Apart from above, an electrolytic solution was prepared by dissolving 0.045 g sodium iodide, NaI, 1.52 g 1-propyl-2,3-dimethylimidazolium iodide, 0.152 g iodine, 12, and 0.081 g of 4-tert-butylpyridine in 3 g of methoxypropionitrile.

The electrolytic solution was injected into the interior of the dye-sensitized photovoltaic device 10 through an introduction port, which was the gap between the transparent substrate 1 and the film-shaped packaging member 6 at the joint 11b, and the pressure was reduced to eliminate bubbles inside the device 10. Next, the joint 11b, which was left unjoined, was sealed under a reduced pressure by using a vacuum sealer so as to complete preparation of the dye-sensitized photovoltaic device 10.

### Example 2

The dye-sensitized photovoltaic device 20 shown in FIG. 3 was prepared. A transparent film having a surface subjected to antireflection treatment was attached to the light incident side surface of the transparent substrate 1 so as to serve as the light-incident-side film-shaped packaging member 22. This light-incident-side film-shaped packaging member 22 was bonded to the film-shaped packaging member 21 constituted by a three-layer film of polyethylene/aluminum/nylon by using maleic anhydride-modified polyethylene as a heat-sealing resin. Except for this, the same procedure as Example 1 was taken to complete preparation of the dye-sensitized photovoltaic device 20.

### Comparative Example 1

The dye-sensitized photovoltaic device 100 shown in FIG. 6 was prepared. A glass substrate 1.1 mm in thickness in which a liquid injection port 108 having a diameter of 0.5 mm was formed in advance was used as the counter substrate 106. The counter electrode 105 was formed by forming a FTO layer as a conductive layer 105a by a sputtering method on the counter substrate 106 and then sequentially forming a chromium layer 500 Å in thickness and a platinum layer 1000 Å in thickness thereon by a sputtering method so as to form the platinum layer 105b.

The semiconductor electrode layer 103 supporting the photosensitizing dye is arranged to oppose the counter electrode 105, and the transparent substrate 101 is attached to the counter substrate 106 in the region where the semiconductor electrode layer 103 is not formed. At this time, as in Example 1, the transparent substrate 101 was joined to the counter substrate 106 with a heat-sealing adhesive film.

After the electrolytic solution was injected into the dye-sensitized photovoltaic device 100 from the liquid injection port 108 by using a liquid feed pump, the pressure was reduced to eliminate bubbles inside the device 100. Next, a heat-sealing film was used as the adhesive layer 109 and a glass plate was used as the end seal 110 to seal the liquid injection port 108 to thereby complete preparation of the dye-sensitized photovoltaic device 100.

### <Evaluation of Performance Of Dye-Sensitized Photovoltaic Devices>

In the dye-sensitized photovoltaic devices 10, 20 and 100 of Examples 1 and 2 and Comparative Example 1 prepared as described above, the maximum thickness of the functional device at the protruded portion was measured by using a digital vernier caliper. The results are shown in Table 1. It can be understood from Table 1 that the dye-sensitized photovoltaic devices 10 and 20 of Examples 1 and 2 based on the present invention achieve significant thickness reduction compared to the dye-sensitized photovoltaic device 100 of Comparative Example 1 having a known structure.

TABLE 1

| | Maximum thickness of electronic |
|---|---|
| | device (mm) |
| Example 1 | 1.45 |
| Example 2 | 1.67 |
| Comparative Example 1 | 2.83 |

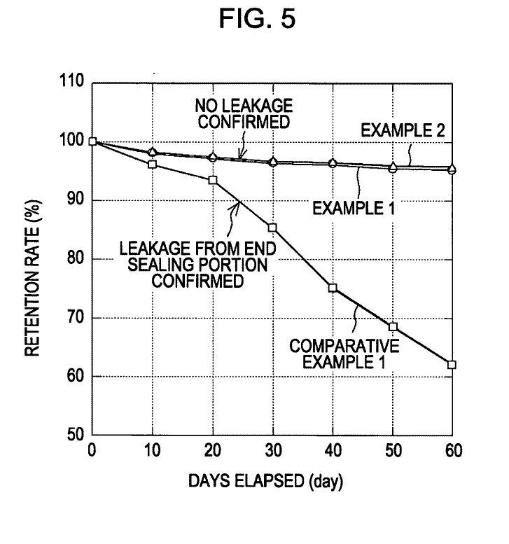

Next, for the dye-sensitized photovoltaic devices 10, and 100 of Examples 1 and 2 and Comparative Example 1, the photoelectric conversion efficiency under irradiation with simulated sunlight (AM 1.5, 100 mW/cm²) was measured every 10 days. The measurement results are shown in FIG. 5.

FIG. 5 is a graph showing the retention rate of the photoelectric conversion efficiency of the dye-sensitized photovoltaic devices of Examples 1 and 2 based on the present invention and Comparative Example 1, and indicates the retention rate of the photoelectric conversion efficiency by assuming the photoelectric conversion efficiency observed on the first day to be 100%. It can be understood from FIG. 5 that the dye-sensitized photovoltaic devices 10 and 20 based on the present invention have high sealing performance and high retention rate of the photoelectric conversion efficiency.

The present invention has been described above on the basis of the embodiments and examples. However, the present invention is in no way limited to these examples and, as a matter of course, various alternations and modifications are possible without departing from the essence of the present invention.

For example, in a functional device that does not require high rigidity as a whole, a thin flexible member may be used as the base member to achieve further thickness reduction and to fabricate a functional device having a flexible shape mountable to a curved surface or the like.

### INDUSTRIAL APPLICABILITY

The present invention is applicable to and contributes to prevailing of dye-sensitized solar cells or the like having a structure suitable for thickness reduction and achieving excellent long-term stability and productivity.

1. A functional device comprising:
a counter electrode located between a base member provided with a second electrode and a flexible member arranged to oppose the base member;
wherein the counter electrode faces the second electrode; and
wherein a functional substance is disposed between the second electrode and the counter electrode.

2. The functional device according to claim 1, wherein the functional substance is enclosed by joining the base member and the flexible member with each other at a peripheral portion.

3. The functional device according to claim 2, wherein the flexible member acts as a packaging member and is composed of a material having a high capacity for suppressing movements of solvents, gasses, and/or water between the functional substance and outside environment.

4. The functional device according to claim 2, wherein the joining is performed by heat-sealing, thermosetting, or ultraviolet curing of an adhesive member.

5. The functional device according to claim 1, wherein the second electrode is located on a first side of the base member and
wherein a whole or a part of a surface of the base member opposite to the first side is covered with a second flexible member connected to the flexible member, and the functional substance is enclosed by first joining of the base member to the flexible member and/or the second flexible member at a peripheral portion and/or by second joining of the flexible member to the second flexible member at a peripheral portion.

6. The functional device according to claim 5, wherein the flexible member and the second flexible member, act as a packaging member and are composed of a material having a high capacity of suppressing movements of solvents, gasses, and/or water between the functional substance and outside environment.

7. The functional device according to claim 5, wherein the first joining and the second joining are performed by heat-sealing, thermosetting, or ultraviolet curing of an adhesive member.

8. The functional device according to claim 1, wherein the counter electrode is arranged without being fixed onto the flexible member.

9. The functional device according to claim 1, wherein the base member is composed of a light-transmitting material so that the device is configured to be a device having a photoelectric conversion function.

10. The functional device according to claim 9, wherein a whole or a part of a light-incident-side surface of the base member is covered with a light-transmitting connected flexible member connected to the flexible member.

11. The functional device according to claim 10, wherein the functional substance is enclosed by first joining of the base member to the flexible member and/or the light-transmitting connected flexible member at a peripheral portion and/or by second joining of the flexible member to the light-transmitting connected flexible member at a peripheral portion.

12. The functional device according to claim 9, configured as a dye-sensitized photovoltaic device in which a semiconductor electrode layer supporting a photosensitizing dye is formed as the electrode at a light-transmitting-side of the base member, an electrolyte layer is provided as the functional substance, electrons of the photosensitizing dye excited by light absorption are extracted to the semiconductor electrode layer, and the photosensitizing dye that lost the electrons is reduced with a reductant in the electrolyte layer.

13. A method for making a functional device in which a counter electrode is provided between a base member provided with a second electrode and a flexible member arranged to oppose the base member, the counter electrode facing the second electrode, and a functional substance is disposed between the second electrode and the counter electrode, wherein:
the functional substance is enclosed by joining the base member to the flexible member at a peripheral portion, or
the second electrode is located on a first side of the base member and a whole or a part of the surface of the base member opposite to the first side is covered with a second flexible member connected to the flexible member, and the functional substance is enclosed by first joining of the base member to the flexible member and/or the second flexible member at a peripheral portion and/or by second joining of the flexible member to the second flexible member at a peripheral portion,
the method comprising:
leaving, unjoined, a part of a joint of the first and/or second joining before introduction of the functional substance so as to function as an introduction port for the functional substance, and, after the introduction of the functional substance, joining the part.

14. The method for making the functional device according to claim 13, wherein the first and/or second joining are performed by heat-sealing, thermosetting, or ultraviolet curing of an adhesive member.
